(19) United States
(12) Patent Application Publication
(10) Pub. No.: US 2023/0074081 A1
(43) Pub. Date: Mar. 9, 2023

(54) DEVICE AND METHOD FOR COATING CHANNELS OF A SAMPLE BY MEANS OF VAPOR DEPOSITION

(71) Applicant: Universität Hamburg, Hamburg (DE)

(72) Inventors: Manuel Müller, Hamburg (DE); Irene Fernandez-Cuesta, Hamburg (DE); Robert Zierold, Hamburg (DE)

(73) Assignee: Universität Hamburg, Hamburg (DE)

(21) Appl. No.: 17/795,713

(22) PCT Filed: Jan. 12, 2021
(86) PCT No.: PCT/EP2021/050466

§ 371 Date: Jul. 27, 2022

(30) Foreign Application Priority Data
Jan. 29, 2020 (DE) 10 2020 102 076.7

(51) Int. Cl. C23C 16/04; C23C 16/455

(52) U.S. Cl. CPC C23C 16/045; C23C 16/45555

(57) ABSTRACT

A method for coating one or more channels of a sample using a vapor deposition includes alternatingly supplying at least two gaseous precursor to one or more channels defined in a sample through at least one feed line that is connected to a first channel end of the one or more channels. An adjustable pressure gradient is generated and conducts the at least two gaseous precursors along a first flow direction (SR1) from the at least one feed line to a first discharge line through the one or more channels. The at least two gaseous precursor and reaction products are discharged from the one or more channels through a first discharge line that is connected to a second channel end of the one or more channels of the sample. Non-reacted precursors and reaction products are discharged through a second discharge line that is connected to the first channel end.

### CROSS REFERENCE TO RELATED INVENTION

This application is a national stage application pursuant to 35 U.S.C. § 371 of International Application No. PCT/EP2021/050466, filed on Jan. 12, 2021, which claims priority to, and benefit of, German Patent Application No. 10 2020 102 076.7, filed Jan. 29, 2020, the entire contents of which are hereby incorporated by reference.

### TECHNOLOGICAL FIELD

The invention relates to a device and a method for coating channels by means of vapor deposition. This can be atomic layer deposition (ALD) or chemical vapor deposition (CVD), for example.

### BACKGROUND

It is known that vapor deposition is used to deposit thin layers on a sample. One or more precursors carrying the material that is to be deposited are introduced into a reaction chamber and react chemically with the surface of the sample and/or with each other to form a coating on the sample. The precursors can also contain an inert gas as a carrier gas in addition to the material that is to be deposited. During a deposition cycle, the various precursors are alternatingly introduced into the reaction chamber, wherein the reaction chamber is flushed with an inert gas between deposition processes in order to remove any remaining precursors and reaction products. Known devices for vapor deposition typically comprise a relatively large reaction chamber compared to the sample, within which the alternatingly introduced precursors are uniformly distributed as a result of diffusion. A deposition of the precursors on the sample also occurs here, with the aforementioned reaction occurring on the sample surface.

Based on the operating principle as explained, this type of vapor deposition is well-suited for coating surfaces. For instance, both flat and structured surfaces can be coated uniformly in this way. However, difficulties arise when internal sample structures are coated, in particular when they are in the micrometer range or below and have a large aspect ratio. In the known vapor deposition process, the precursors can barely penetrate into the channels in particular in the micrometer range or below. This is due to the diffusive distribution of the precursors. In small channels, this diffusion process takes a very long time and might not result in sufficient coating of the internal structures.

In general, internal structures with cross-sectional sizes, particularly in the micrometer range or below, can be coated with a liquid-based atomic layer deposition, for example. In this instance, in contrast to vapor deposition, the precursors are provided in the liquid phase. However, the flow rates are very low because of the small structures. Moreover, it is difficult to portion feed pulses in nanostructures. Low flow rates and a mixing of liquid precursors result in side reactions and long process times. Furthermore, due to their reactivity, the solvents of the precursor and the liquids used for rinsing often cause damage to the structures that are to be coated or to other undesirable reactions.

Therefore, so-called flow-through reactors for coating nanostructures have been proposed, for example in Chen et al. in the publication “Toward highly efficient photocatalysis: a flow-through Pt@TiO2@AAO membrane nanoreactor prepared by atomic layer deposition” in Chemical Communications 2014, 50, 4379, and in Liu et al. in the publication “Uniform coating of TiO2 on high aspect ratio substrates with complex morphology by vertical forced-flow atomic layer deposition” from RSC Advances, 2017, 7, 34730. In flow-through reactors of this type, a pressure gradient is created across the channels that are to be coated from the inside, thereby forcing a flow through the channels. This leads to more efficient coating, since the process does not occur merely diffusively. The proposed flow-through reactors have some disadvantages, though. For example, typically only channels with an aspect ratio no greater than 1:500 can be reliably coated internally. Moreover, the pressure gradient often varies quite significantly, depending in particular upon the internal coatings, which continually increase during the deposition process. This results in unreliable and poorly reproducible coating.

On this basis, the invention addresses the problem of coating channels internally by means of vapor deposition in a reliable way with efficient process times.

### BRIEF SUMMARY OF THE INVENTION

The invention relates to a device for coating channels by means of vapor deposition, comprising a sample that has channels, at least one feed line, which is connected to first channel ends of the channels for supplying gaseous precursors into the channels, a first discharge line, which is connected to second channel ends lying opposite the first channel ends for discharging precursors and reaction products emerging from the channels, characterized in that the device comprises a second discharge line, which is connected to the first channel ends, wherein a control unit is further provided, which is configured to alternatingly supply at least two different precursors to the channels through the first channel ends via the at least one feed line, to conduct a precursor flow along a first flow direction from the feed line through the channels to the first discharge line while the precursors are being supplied by generating an adjustable pressure gradient, and to discharge unreacted precursors and reaction products via the second discharge line.

The invention additionally relates to a method for coating channels of a sample by means of vapor deposition, wherein gaseous precursors are supplied to the channels via at least one feed line, which is connected to first channel ends of the channels, and are discharged from the channels together with reaction products via a first discharge line, which is connected to second channel ends lying opposite the first channel ends, characterized in that at least two different precursors are alternatingly supplied to the first channel end via the at least one feed line, in that, while the precursors are being supplied, a precursor flow is conducted along a first flow direction from the feed line to the first discharge line through the channels by generating an adjustable pressure gradient, and in that non-reacted precursors and reaction products are discharged via a second discharge line, which is connected to the first channel end.

In particular, the vapor deposition can be ALD or CVD. Each of the channels of the sample to be coated extends from the first channel end to the opposite second channel end. Precursors are supplied to these channels via the at least one feed line, enter the channels at the first channel ends and flow through the channels. The precursors then react with the inner surfaces of the channels such that the material that is to be deposited is deposited on the inner surfaces of the channels. A portion of the supplied precursors that has not reacted with the inner surfaces of the channels, as well as any reaction products, emerge from the channels at the second channel ends and are discharged via the first discharge line. By means of the control unit according to the invention, at least two different precursors are alternatingly supplied to the channels via the first channel end. In principle, the precursors can be supplied through the same feed line or through separate feed lines. The precursors comprise the material that is to be deposited on the sample, in particular in the channels. Furthermore, the precursors can comprise an inert gas as carrier gas. A pressure gradient is established between the channel ends of the sample in order to achieve efficient flow through the channels. This results in the aforementioned precursor flow along the first flow direction from the feed line through the channels to the first discharge line. Due to the pressure gradient, the precursors can reach the channels in the interior, in particular over their entire length, and can coat them in a reliable way with efficient process times.

In an embodiment, the pressure gradient is adjustable. This does not merely generate a flow through the channels that is substantially uncontrolled, as in the prior art. Rather, the pressure gradient can be precisely adjusted by means of the control unit. The pressure gradient can be adapted to the diameter of the channels, for example. The device according to the invention can thus be used, for example, to internally coat channels with a diameter in the millimeter range, but in particular in the micrometer and nanometer range, as well. The device is thus additionally suitable for reliably coating channels with highly varied aspect ratios, especially channels with aspect ratios of greater than or equal to 1:1,000, for example, in particular even greater than or equal to 1:10,000. In particular, the precursor flow can be kept substantially constant throughout the deposition process, and so efficient and reliable coating remains possible even as the coating increases and the diameter of the channels narrows.

This is also aided, in particular, by the fact that unreacted precursors are discharged via the second discharge line. The unreacted precursors can be precursors that did not enter the channels when being supplied and/or material of the precursors that is physisorbed within the channels. According to the invention, the second discharge line is connected to the first channel ends, i.e. to the channel ends that are also connected to the at least one feed line. As the inventors have determined, despite the established pressure gradient, an accumulation of precursor molecules and reaction products can occur in the region of the first channel ends when precursors are supplied to the first channel ends. In particular, the inventors have determined that reaction products and excess precursors might not be reliably discharged via the first discharge line, which is connected to the second channel ends that are facing away. This results in insufficient coating and/or excessive process times. Owing to the second discharge line provided with the first channel ends, a reliable discharge of reaction products and remaining precursors can take place during the alternating flushing processes and deposition processes. The described accumulation at the first channel ends is thereby prevented. This will be illustrated by an example.

During a deposition cycle, for example, trimethylaluminum (TMA) in the gas phase can be supplied as the first precursor to the first channel ends via the at least one feed line. Due to the pressure gradient that is applied across the channels, a precursor flow of the TMA forms and flows from the first channel ends through the channels to the second channel ends. The TMA reacts on the inner surface of the channels with OH groups located there and yields CH₄ as a reaction product. Aluminum is deposited on the inner surface of the channels; in particular dimethylaluminum or O—Al—(CH₃)₂ is formed. This can result in the aforementioned accumulation of precursors, in this case TMA, or reaction products, in this case CH₄, in the region of the first channel ends, which could impede the entry of further TMA molecules and in particular of the subsequently supplied second precursor. In a subsequent step, TMA that has not entered the channels, as well as the reaction product CH₄ and any physisorbed precursors, are therefore discharged not, or not only, on the discharge side via the first discharge line—as in the prior art—but rather on the feed side, i.e. at the first channel ends. In this way, the channels are freed from any accumulated molecules. In particular, a flushing process with inert gas can still take place here, as will be discussed later. In a subsequent step, the second precursor is then supplied to the first channel ends via the at least one feed line and is conducted as a precursor flow through the channels to the first discharge line as a result of the pressure gradient. For example, H₂O can be provided as the second precursor. The H₂O again reacts with the dimethylaluminum or O—Al—(CH₃)₂ groups that have been deposited within the channels so as to yield CH₄ as a reaction product. An Al—OH group remains on the inner sides of the channels, which in turn is suitable for reacting with TMA. An accumulation of second precursor, in this case H₂O, and the reaction product CH₄ in the region of the first channel ends can also occur in this deposition step. Therefore, in a subsequent step, remaining material, in particular the second precursor and the reaction product, is again discharged via the second discharge line. Flushing with inert gas can take place here, as well, as will be discussed below. A clogging of the channels can thus be prevented by the second discharge line with the first channel ends that is provided according to the invention. This permits the reliable and efficient coating even of especially long channels with an aspect ratio of greater than 1:1,000 or even greater than 1:10,000. It is thus possible to internally coat the channels formed in a sample in a particularly reliable and efficient way by the process according to the invention.

The at least one feed line and the first discharge line are connected to the sample in particular in such a way that the precursor flow can be conducted only through the channels of the sample. If the precursor flow only passes through the channels of the sample, the pressure gradient can be set in a particularly specific and reliable manner.

According to an embodiment, the control unit is configured to set the pressure gradient by means of the volumetric flow rate of the precursors supplied via the at least one feed line and/or by means of a negative pressure applied to the first discharge line. According to one embodiment of the method, the pressure gradient can be set by means of the volumetric flow rate of the precursors supplied via the at least one feed line and/or by means of a pressure applied to the first discharge line. On the one hand, it is thus possible to set a specific setting of the pressure gradient by means of the amount of precursors supplied, i.e. by means of a pressure on the side of the first channel ends. On the other hand, the pressure gradient can be set by means of the pressure that is present at the second channel ends and thus at the first discharge line. To generate the pressure gradient, a higher pressure is set at the first channel ends than at the second channel ends, which leads to the formation of the precursor flow. The adjustability of the pressure gradient according to the invention can be achieved by regulating the pressure ratios. The negative pressure applied to the first discharge line and thus to the second channel ends can be generated by a vacuum pump connected to the first discharge line, for example. This vacuum pump can be controlled by the control unit. In particular, the supply of the precursors and thus the corresponding volumetric flow rate can be pulsed. The pressure gradient can then also be controlled by controlling the pulses, such as by modifying the duration of the pulses.

According to an embodiment, the control unit is configured to supply an inert gas to the sample as a flushing gas during the discharge. According to a corresponding embodiment of the method, an inert gas is supplied to the sample as a flushing gas during the discharge. The flushing gas can be used to reliably clean the channels or, respectively, the regions around the first channel ends or the second channel ends particularly, i.e. to remove precursors or reaction products that did not enter the channels while they were being supplied. In particular, physisorbed precursors can be reliably discharged from the channels in this way, which is important for ALD and CVD, for example. The discharge can occur via the first discharge line and/or the second discharge line. For example, the inert gas can be supplied to the first channel ends via one of the at least two feed lines and/or to the second channel ends via a further feed line. Preferably, for instance, the flushing gas can be supplied to the channels via a further feed line that is connected to the second channel ends, flow through the channels in particular as a result of a pressure gradient, and be discharged via the second discharge line. The supply can also occur, for example, via one or more of the feed lines connected to the first channel ends, and the discharge can occur via the second discharge line, which is also connected to the first channel ends. In this instance, the flushing gas does not necessarily pass through the canals unless it is also simultaneously discharged via the first discharge line. Any accumulation of molecules in the region of the first channel ends can be discharged especially reliably through the second discharge line by the flushing gas, in particular when the flushing gas is supplied on the side of the second channel ends via the further feed line and discharged via the second discharge line.

Thus, according to another embodiment, the control unit is configured to conduct the precursor flow through the channels in the first flow direction and a flow of an inert gas in a second flow direction, which is opposite the first flow direction. According to a corresponding embodiment of the method, the precursor flow is conducted through the channels in the first flow direction and a flow of an inert gas in a second flow direction, which is opposite the first flow direction. While the precursor flow runs along the first flow direction via the at least one feed line to the first channel ends, through the channels to the second channel ends and to the first discharge line, the flow of the inert gas runs in the opposite direction, that is, from the second channel ends through the channels to the first channel ends, and is discharged in particular via the second discharge line. The inert gas can be supplied via the aforementioned additional feed line on the sides of the second channel ends and discharged via the second discharge line provided on the sides of the first channel ends. In particular, the precursor flow in the first flow direction and the flow of the inert gas in the second flow direction can be alternatingly conducted through the channels. The aforementioned flushing processes thus result in particularly reliable cleaning, i.e. the removal of any accumulated precursors and reaction products, in particular in the region of the first channel ends.

According to an embodiment, the control unit is configured to set the pressure gradient by means of a volumetric flow rate of an inert gas. In particular, the inert gas is supplied to the second channel ends via a feed line that is connected to the second channel ends. According to a corresponding embodiment of the method, the pressure gradient is set by means of a volumetric flow rate of an inert gas, wherein the inert gas is supplied to the second channel ends in particular via a feed line connected to the second channel ends. As has been mentioned, a further feed line can be provided, which is connected to the second channel ends. The pressure on the side of the second channel ends can be adjusted particularly reliably by a supply of inert gas, especially if a vacuum pump is also provided at the first discharge line. The pressure on the side of the second channel ends can thus be raised by increasing the volumetric flow rate of the inert gas, and it can be reduced by discharging the inert gas through the first discharge line. A desired pressure level, and thus pressure gradient, can be achieved by the control unit by precisely setting the supplied and discharged gas. Alternatively or additionally, however, the inert gas can also be supplied to the first channel ends, for example via one of the at least two feed lines or via a separate feed line. In particular, as mentioned, the precursors can comprise inert gas of this type in addition to the material to be deposited. Accordingly, the pressure can also be controlled in this way on the side of the first channel ends.

According to an embodiment, the control unit is configured to specifically increase the pressure gradient as the diameter of the channels decreases as a result of the deposition of material on the inner surface of the channels. According to a corresponding embodiment of the method, the pressure gradient is specifically increased as the diameter of the channels decreases as a result of the deposition of material on the inner surface of the channels. As has been discussed, the material deposited by the precursors on the inner surface of the channels accumulates in multiple layers on top of each other and hereby results in a reduction in the diameter of the channels. With each additional deposition cycle, any further deposition becomes more difficult due to this cross-sectional narrowing. It is possible to compensate for this, however, due to the adjustability of the pressure gradient by the control unit according to the invention. The control unit can specifically increase the pressure gradient by means of the pressure conditions at the opposite ends of the channel. In particular, the pressure gradient can be increased in such a way that the volumetric flow rate through the channels remains constant. The control unit can thus be designed to keep the precursor flow constant. Therefore, reliable and efficient coating can be achieved even over many deposition cycles.

According to an embodiment, the control unit is configured to adjust the pressure gradient in such a way that a desired flow regime, in particular a Knudsen flow, is maintained at least in some sections within the channels during the deposition. According to one embodiment of the method, a desired flow regime, in particular a Knudsen flow, is maintained at least in some sections within the channels during the deposition. Preferably, the desired flow regime, in particular the Knudsen flow, is maintained over the entire length of the channels. Accordingly, the control unit can generate a desired flow regime, in particular by means of the pressure conditions at the opposite sides of the channels, and can maintain it even when the diameter of the channels decreases as the coating progresses. In particular, it is possible to maintain a flow regime that allows for an especially efficient and reliable coating. In particular, this is the Knudsen flow, i.e. the transitional from viscous flow to molecular flow.

According to another embodiment, the channels of the sample have an aspect ratio of greater than 1:1,000, preferably greater than 1:10,000, particularly preferably greater than 1:20,000. According to one embodiment, the channels have a diameter in the millimeter range or below, preferably in the micrometer range or below, particularly preferably in the nanometer range or below. Owing in particular to the second discharge line and the adjustability of the pressure gradient, the device according to the invention allows for a reliable and efficient coating of the inner surface of channels with diameters this small and aspect ratios this large. In particular, it is possible to coat channels with a diameter in the nanometer range and an aspect ratio of greater than 1:10,000 and even greater than 1:20,000.

### BRIEF DESCRIPTION OF THE DRAWINGS

An embodiment of the invention is explained in the following other figures.

FIG. 1 schematically illustrates an example of a prior art device for vapor deposition.

FIG. 2 schematically illustrates an embodiment of the inventive device for vapor deposition.

If not otherwise specified, the same reference numbers indicate the same objects below.

### DETAILED DESCRIPTION OF THE INVENTION

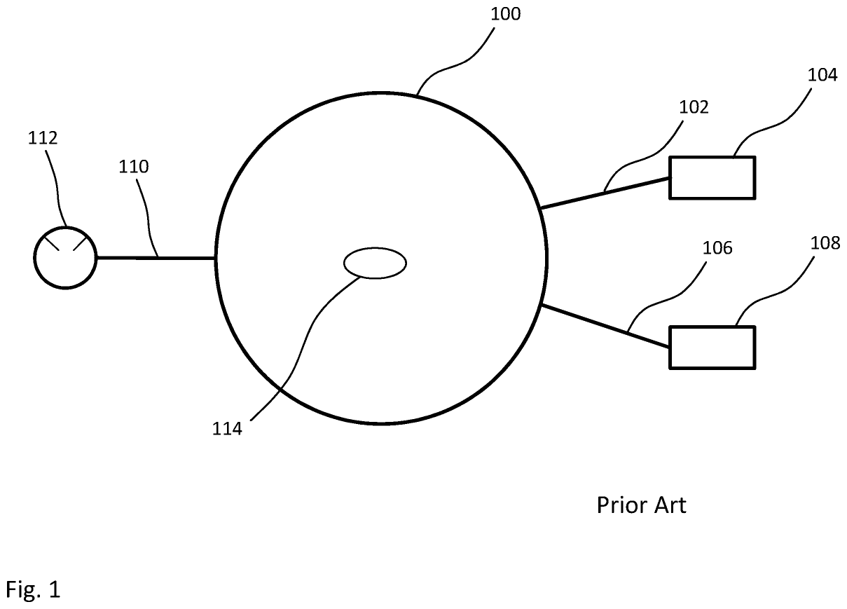

A device for vapor deposition, in particular for atomic layer deposition, according to the prior art is illustrated in FIG. 1. This device comprises a large reaction chamber 100, to which a first precursor is supplied from a reservoir 104 via a feed line 102 and a second precursor is supplied from a reservoir 108 via a feed line 106. Naturally, additional precursors can also be supplied via these feed lines or additional feed lines. In addition to the material that is to be deposited, the precursors can also comprise an inert gas as a carrier gas. The two precursors are distributed evenly in the evacuated reaction chamber 100 by diffusion and, in the process, also adhere to a sample 114, and thus react with the sample. The sample 114 can be retained on a sample holder, which is not shown. The precursors are supplied to the chamber 100 alternatingly and react on the sample surface to form atomic layers. For example, atomic layers of metal oxides, in particular AL2O3, can be formed on the sample. The reaction chamber can be evacuated via a discharge line 110 and a vacuum pump 112 that is attached to it. In particular, the chamber can also be flushed via the discharge line 110 and a feed line for inert gas, which is not shown.

Surfaces of a sample can generally be coated well with a known reaction chamber such as this. Nevertheless, the internal structures, especially the inner surfaces of channels, cannot be coated successfully or only with inefficiently long process times. This is due in particular to the fact that the precursors cannot be diffusively distributed, or only very slowly, along the interior of the channels.

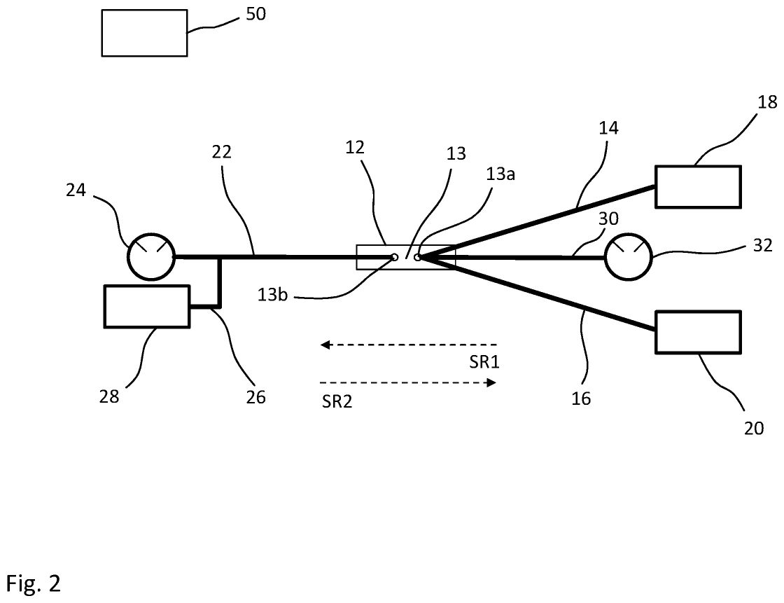

A device according to the invention is illustrated schematically in FIG. 2. This device for coating channels by means of vapor deposition comprises a sample 12 with channels 13 that are formed within it. The sample can be arranged in a sample holder, which is not shown. The device further comprises a first feed line 14 for supplying a first gaseous precursor from a reservoir 18 and a second feed line 16 for supplying a second precursor from a reservoir 20. The feed lines 14, 16 are connected to a first channel end 13a of the channels 13 formed in the sample 12. Furthermore, the device comprises a first discharge line 22, which is connected to the first channel ends 13a lying opposite the second channel ends 13b of the channels 13. A vacuum pump 24 is connected to the first discharge line 22.

During a deposition process, the first precursor and the second precursor are supplied alternatingly to the first channel ends 13a via the first feed line 14 and via the second feed line 16, respectively. A negative pressure is generated in the first discharge line 22, and thus at the second channel ends 13b, by means of the vacuum pump 24. Different pressure conditions thus exist in the area of the first channel ends 13a and in the area of the second channel ends 13b, which leads to the establishment of a pressure gradient. Owing to the pressure gradient, a precursor flow of first precursor and second precursor, respectively, is generated along a first flow direction SR1 from the first channel ends 13a through the channels 13 via the second channel ends 13b to the first discharge line 22. As a result of the pressure gradient, the precursors reliably reach the entire inner surface of the channels, not only in the area of the first channel ends, but especially also in the area of the second channel ends. This leads to a coating that is complete, uniform and, due to low process times, efficient.

In an embodiment, this pressure gradient can be adjusted via a control unit 50. In particular, the control unit 50 controls the supply of the first precursor via the feed line 14, the supply of the second precursor via the feed line 16 and the discharge via the first discharge line 22. For this purpose, the control unit 50 controls valves that are provided in particular on the feed line side and/or discharge line side. The control unit 50 also controls the vacuum pump 24. For example, the control unit 50 can adjust the pressure gradient by adjusting the quantity and thus the volumetric flow rate of the precursor (possibly including the carrier gas) that is supplied via the feed lines 14, 16, or by adjusting the negative pressure applied to the first discharge line 22 by controlling the vacuum pump 24. In particular, the supply of first precursor and second precursor can be pulsed, wherein the control unit 50 can adjust the pressure gradient by controlling the duration of the pulses, for example. In particular, the control unit can set a specific pressure gradient as a function of the diameter and aspect ratio of the channels in the sample.

The device further comprises a reservoir 28 for inert gas, which can be supplied to the channels 13 via a further feed line 26, which is connected to the second channel ends 13b. In the present example, the feed line 26 is identical in some sections to the first discharge line 22. The supply of inert gas from the reservoir 28 is likewise controlled by the control unit 50. For example, the control unit 50 can supply inert gas from the reservoir 28 to the area of the second channel ends 13b via the feed line 26 in order to adjust the pressure gradient. In this way, in particular in coordination with the vacuum pump 24 and thus the discharge line 22, the pressure on the side of the second channel ends 13b can be not only reduced but also increased and therefore finely adjusted. Furthermore, flushing the channels 13 with inert gas can take place between deposition processes, i.e. between the processes of supplying the first precursor and the second precursor, respectively. For example, after the first precursor has flowed through the channels 13 along the first flow direction SR1 from the first channel ends 13a, through the channels 13 via the second channel ends 13b, a flushing process can take place in the opposite direction. Inert gas is then conducted along an opposite second flow direction SR2 from the reservoir 28 via the second channel ends 13b, through the channels 13 and via the first channel ends 13a. According to the invention, a second discharge line 30, which is connected to the first channel ends 13a, is provided. This line leads to a further vacuum pump 32, but can alternatively or additionally also be connected to the vacuum pump 24. The flow of flushing gas conducted through the channels along the flow direction SR2 is discharged via the second discharge line 30. In this way, precursors that have not entered the channels during the supplying process, as well as their reaction products and any physisorbed precursors, are discharged.

Flushing in the opposite direction allows for the most complete removal of precursors and reaction products. In particular, any accumulation of precursor molecules and/or reaction products that may have occurred in the region of the first channel ends 13a can be reliably removed in this way. In addition, precursors within the channels and physisorbed on the inner surface of the channels can also be discharged from the channels in a particularly reliable manner. These accumulations are reliably pumped away by means of the vacuum pump 32 and via the second discharge line 30. Therefore, owing in particular to the second discharge line, channels with an especially small diameter, such as in the nanometer range, and an especially large aspect ratio, such as 1:10,000, can also be coated reliably and efficiently.

The project leading to the present application has received funding from the European Research Council (ERC) under the European Union's Horizon 2020 research and innovation program (grant agreement No. 714073).

### LIST OF REFERENCE SIGNS

### 12 Sample

13a First channel end
13b Second channel end
14 First feed line
16 Second feed line

### 18 Reservoir

### 20 Reservoir

22 First discharge line
24 Vacuum pump
26 Feed line

### 28 Reservoir

30 Second discharge line
32 Vacuum pump
50 Control unit
100 Reaction chamber
102 Feed line

### 104 Reservoir

106 Feed line

### 108 Reservoir

110 Discharge line
112 Vacuum pump
114 Sample holder
SR1 First flow direction
SR2 Second flow direction

1-15. (canceled)

16. A device for coating channels by means of vapor deposition, comprising:
at least one feed line connected to a first channel end of one or more channels of a sample, wherein the at least one feed line is configured to supply a gaseous precursor into one or more channels of a sample;
a first discharge line positioned opposite the first channel end and connected to a second channel end of the one or more channels of the sample, wherein the first discharge line is configured to discharge the gaseous precursors and reaction products emerging from the one or more channels of the sample;
a second discharge line connected to the first channel end of the one or more channels of the sample; and
a control unit configured to alternatingly supply at least two different gaseous precursors to the at least one channel through the first channel end via the at least one feed line,
wherein a pressure gradient is generated and is configured to supply the gaseous precursor along a first flow direction (SRI) from the feed line through the one or more channels of the sample, and
wherein the pressure gradient is configured to discharge unreacted precursors and reaction products via the second discharge line along a second flow direction (SR2).

17. The device according to claim 16, wherein the control unit is configured to adjust the pressure gradient by means of a volumetric flow rate of the at least two gaseous precursors that are supplied through the at least one feed line.

18. The device according to claim 16, wherein the control unit is configured to adjust the pressure gradient by means of a volumetric flow rate of the at least two gaseous precursors that flows into the first discharge line.

19. The device according to claim 16, wherein the control unit is configured to supply an inert gas to the sample as a flushing gas during discharge.

20. The device according to claim 19, wherein the control unit is configured to conduct the flow of the at least two gaseous precursors through the one or more channels of the sample in the first flow direction (SR1) and a flow of the inert gas in the second flow direction (SR2), wherein the second flow direction (SR2) is opposite that of the first flow direction (SR1).

21. The device according to claim 19, wherein the control unit is configured to adjust the pressure gradient by adjusting a volumetric flow rate of the inert gas, wherein the inert gas is supplied to the second channel end via a feed line configured to be connected to the second channel end.

22. The device according to claim 16, wherein the control unit is configured to increase the pressure gradient as a diameter of the one or more channels of the sample decreases as a result of deposition of material on an inner surface of the one or more channels.

23. The device according to claim 16, wherein the control unit is configured to adjust the pressure gradient to maintain a Knudsen flow in at least in some sections of the one or more channels during deposition of material on an inner surface.

24. The device according to claim 16, wherein the one or more channels of the sample comprise an aspect ratio of greater than 1:1,000.

25. The device according to claim 16, wherein the one or more channels of the sample comprise an aspect ratio greater than 1:20,000.

26. The device according to claim 25, wherein the one or more channels comprise a diameter of less than one (1) micrometer.

27. A method for coating one or more channels of a sample using a vapor deposition, comprising:
alternatingly supplying at least two gaseous precursor to one or more channels defined in a sample via at least one feed line that is connected to a first channel end of the one or more channels of the sample;
generating an adjustable pressure gradient that is configured to conduct the at least two gaseous precursors along a first flow direction (SR1) from the at least one feed line to a first discharge line through the one or more channels;
discharging the at least two gaseous precursor and reaction products from the one or more channels through a first discharge line that is connected to a second channel end of the one or more channels of the sample, wherein the second end is positioned opposite the first end; and
discharging non-reacted precursors and reaction products through a second discharge line that is connected to the first channel end.

28. The method according to claim 27, wherein the adjustable pressure gradient is set using a volumetric flow rate of the at least two gaseous precursors supplied through the at least one feed line.

29. The method according to claim 27, wherein the adjustable pressure gradient is set using a negative pressure that is applied to the first discharge line.

30. The method according to claim 27, further comprising supplying an inert gas to the sample as a flushing gas during the discharging.

31. The method according to claim 30, wherein the inert gas is conducted along a second flow direction (SR2) that is opposite the first flow direction (SR1), and wherein the inert gas and the at least two gaseous precursors are alternatingly conducted through the one or more channels of the sample.

32. The method according to claim 27, wherein the pressure gradient is generated by a volumetric flow rate of an inert gas, and wherein the inert gas is supplied to the second channel end through a feed line that is connected to the second channel end.

33. The method according to claim 27, wherein the adjustable pressure gradient is increased as a diameter of the one or more channels of the sample decreases due to a deposition of material on an inner surface of the one or more channels.

34. The method according to claim 27, wherein a Knudsen flow is maintained at least in some sections within the one or more channels of the sample during the vapor deposition.
